(19) United States
(12) Patent Application Publication
(10) Pub. No.: US 2026/0126497 A1
(43) Pub. Date: May 7, 2026

(54) INTELLIGENT POWER MANAGEMENT SYSTEM AND METHOD FOR MONITORING BATTERY DEGRADATION

(71) Applicant: SEMICONDUCTOR COMPONENTS INDUSTRIES, LLC, Scottsdale, AZ (US)

(72) Inventor: Hideo KONDO, Oizumi-machi (JP)

(73) Assignee: SEMICONDUCTOR COMPONENTS INDUSTRIES, LLC, Scottsdale, AZ (US)

(21) Appl. No.: 19/073,291

(22) Filed: Mar. 7, 2025

Related U.S. Application Data
(60) Provisional application No. 63/717,482, filed on Nov. 7, 2024.

(51) Int. Cl. G01R 31/392; G01R 31/367; G01R 31/371; G01R 31/3842

(52) U.S. Cl. CPC G01R 31/392; G01R 31/367; G01R 31/371; G01R 31/3842

(57) ABSTRACT

A battery monitoring system for a battery includes a sensor array, a processor, and memory. The sensor array measures battery parameters, including an ambient temperature and a battery voltage, a battery current, and a battery temperature of the battery. The memory includes instructions. Execution of the instructions causes the processor to record the battery parameters from the sensor array during a charging mode and a discharging mode of the battery, respectively. An accumulated temperature history of the battery is also determined using the ambient temperature and the battery temperature. The processor calculates a total energy loss level of the battery using the battery voltage and current, and then generates a degradation alert in response to the total energy loss level exceeding a loss threshold and the accumulated temperature history exceeding a temperature threshold.

### CROSS-REFERENCE TO RELATED APPLICATIONS

The present application claims the benefit of priority to U.S. Provisional Application No. 63/717,482 filed on Nov. 7, 2024, which is hereby incorporated by reference in its entirety for all purposes.

### INTRODUCTION

Electric vehicles, standby power supplies, power stations, and other mobile and stationary battery electric systems utilize rechargeable electrochemical batteries as energy storage devices. The rechargeability and high energy storage capacities of lithium-ion batteries in particular has led to their widespread adoption in a myriad of different industries. For example, various types of lithium-ion batteries are used to power electric motors in mobile and stationary battery electric systems, as well as to energize actuators, sensors, displays, and control circuitry of a host of different medical devices, industrial systems, and consumer products.

While lithium-ion batteries are essential components of modern battery electric systems, their use comes with potential risks. For instance, the internal temperature of an aged or faulty battery cell can rapidly increase. Thermal management techniques such as circulation of coolant/air, the use of heat sinks, and cell vents are therefore used to help regulate battery temperature. However, when the internal temperature of a battery cell increases beyond a threshold temperature point, the battery cell can begin to melt or burn. Pressure increases within the battery cell, which in turn can cause an outer can or foil of the battery cell to rupture. When a cell rupture occurs, the failing battery cell may expel high-temperature gasses, molten materials, soot, and other ejecta toward neighboring battery cells. This condition, i.e., thermal runaway, can adversely affect operation of the battery and the battery electric system.

### SUMMARY

The present disclosure relates to electrical circuit topologies and control methods for monitoring degradation and a state of health (SOH) of an electrochemical battery. In particular, the disclosed battery monitoring system and method for monitoring battery degradation is based on the battery's total energy loss level, e.g., a total energy loss rate, as well as an accumulated temperature history. The present teachings, which are directed toward detecting a degradation state of the battery without removing the battery from the battery electric system, seek to protect the battery electric system and surrounding surfaces from thermal damage. More specifically, a potentially hazardous degradation state of the battery is detected prior to manifestation of the hazard. The present teachings enable proactive maintenance actions, including but not limited to the issuance of an alert as an advanced warning of an impending battery failure. This in turn provides an operator with sufficient time with which to perform preventive actions such as battery replacement and/or circuit disconnection.

In a possible embodiment, a processor of an electronic monitoring unit (EMU) of the above-noted battery monitoring system records temperatures of the battery over time as a temperature accumulation history. The processor also monitors a total energy input into the battery during a charging mode and a total energy output from the battery during a discharging mode. The difference between the charging and discharging energy values represents a total energy loss level within the battery, i.e., the total energy loss level of the battery may be calculated as an energy loss rate using the energy input rate and the energy output rate, for instance by subtracting the energy output rate from the energy input rate.

When the total energy loss level (which may be calculated as a total energy loss rate) exceeds a calibrated loss threshold, the processor determines whether the battery is in a potentially hazardous state, e.g., by referencing the above-noted temperature accumulation history as an additional criterion.

The above summary is not intended to represent every embodiment or aspect of the present disclosure. Rather, the foregoing summary exemplifies certain novel aspects and features as set forth herein. The above noted and other features and advantages of the present disclosure will be readily apparent from the following detailed description of representative embodiments and modes for carrying out the present disclosure when taken in connection with the accompanying drawings and the appended claims.

### BRIEF DESCRIPTION OF THE DRAWINGS

The drawings described herein are for illustrative purposes only, are schematic in nature, and are intended to be exemplary rather than to limit the scope of the disclosure.

FIG. 1 illustrates a representative battery electric system having a rechargeable battery and a battery monitoring system operable for monitoring a degradation level of the battery in accordance with the present disclosure.

FIG. 2 is a schematic circuit diagram of a battery monitoring system usable as part of the battery electric system of FIG. 1.

FIGS. 3A, 3B, and 3C are time plots illustrating respective charging, discharging, and total energy loss levels in the battery of FIGS. 1 and 2, with time depicted on the horizontal axis and open circuit voltage (OCV) depicted on the vertical axis.

FIG. 4 is a flow chart describing an embodiment for determining a degradation level of the battery shown in FIGS. 1 and 2.

The present disclosure may be modified or embodied in alternative forms, with representative embodiments shown in the drawings and described in detail below. Inventive aspects of the present disclosure are not limited to the disclosed embodiments. Rather, the present disclosure is intended to cover alternatives falling within the scope of the disclosure as defined by the appended claims.

### DETAILED DESCRIPTION

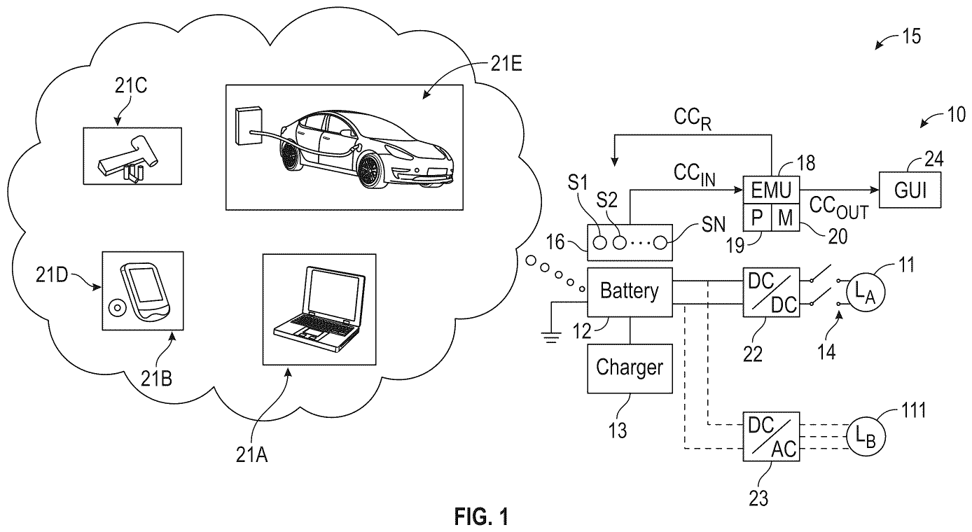

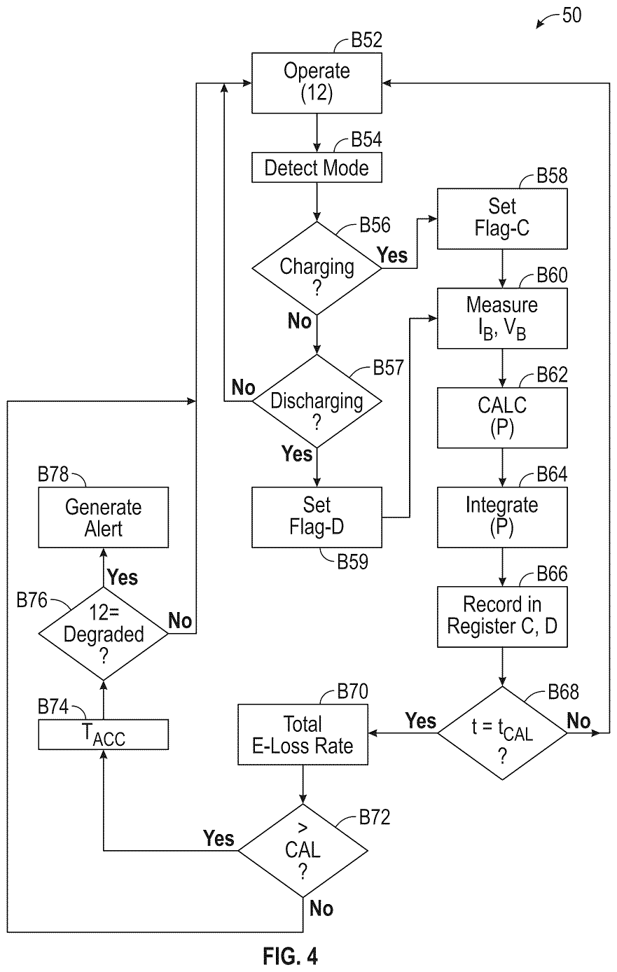

With reference to the drawings, wherein like reference numbers refer to the same or similar components throughout the several views, a battery electric system 10 is illustrated in FIG. 1. The battery electric system 10 in a simplified embodiment includes a rechargeable battery 12, e.g., a lithium-ion battery or battery pack. As noted above, battery degradation is associated with various potential risks, including possible overheating, thermal runaway, and battery failure. The present strategy enables early detection and treatment of potentially hazardous states of the battery 12 by analyzing a total energy loss level (e.g., rate) and accumulated temperature history of the battery 12. An exemplary method 50 for doing so is described below with particular reference to FIG. 4.

The battery electric system 10 illustrated in FIG. 1 may include an electrical disconnect switch 14, a direct current (DC)-powered load (L_{A}) 11 and/or an alternating current (AC)-powered load (L_{B}) 111, and a battery monitoring system 15. The battery monitoring system 15 includes a sensor array 16 and an electronic monitoring unit (EMU) 18. The sensor array 16 is electrically connectable to the battery 12, for instance via one or more hard-wired transfer conductors and/or wireless pathways/network connections.

The EMU 18 in accordance with an exemplary embodiment includes a processor (P) 19 and a non-transitory computer-readable storage medium (“memory”) (M) 20. The memory 20 is programmed with computer-readable code/instructions that are executable by the processor 19 to cause the EMU 18 to perform the method 50 (FIG. 4) when determining a degradation level of the battery 12. Among other actions, the EMU 18 may transmit a measurement request signal (CC_{R}) to the sensor array 16 to initiate sensing actions when measuring battery parameters as part of the battery monitoring process.

The battery 12, which is described hereinafter as a representative lithium-ion (Li)-ion battery for illustrative consistency, may be used as part of a mobile or stationary battery-powered device. For instance, the battery 12 may be used to power a portable electronic device such as a computer 21A, e.g., a tablet, desktop, or laptop computer, or a cellular phone 21B. Other applications may use the battery 12 as part of a medical device, for instance a handheld surgical tool 21C or a wearable device 21D. The optional wearable device 21D may be constructed as a continuous glucose monitor (CGM) as shown, or alternatively as an automatic external defibrillator (AED), a blood oxygen monitor, or an infusion pump, among other possibilities. Likewise, the battery 12 may be used to energize a mobile system 21E such as an electric vehicle, which is illustrated in FIG. 1 as it might appear when undergoing a battery charging process. Still other applications may be readily envisioned, including but not limited to electronic gaming systems, control consoles, or other industrial, medical, or transportation systems. The exemplary use, chemistry, construction, and simplified depiction of the battery 12 herein is therefore illustrative of the present teachings and non-limiting thereof unless otherwise specified.

The representative battery monitoring system 15 illustrated in FIG. 1 may include other components in different embodiments. For example, a direct current-to-direct current (DC/DC) converter 22 may be used with the battery 12 to increase or reduce the battery voltage before energizing the connected load 11. A battery charger 13 may be connectable to the battery 12 and used to recharge the battery 12 as needed. In an alternating current (AC) configuration of the battery electric system 10, the battery 12 may be connected to a DC/AC inverter circuit 23, with the inverter circuit 23 operable for outputting a single phase or polyphase AC waveform to a coupled AC-powered load 111. The loads 11 and 111 may be variously embodied as electric motors, rotary actuators, linear actuators, displays, transducers, and/or other electrical or electromechanical devices depending on the application.

As part of the present battery monitoring strategy, the sensor array 16 via its various sensors S1, S2, . . . , SN as shown in FIG. 1 is configured to measure or sense a set of battery parameters during charging and discharging modes of the battery 12, with “N” being an integer representing an arbitrary N^{th} sensor in the sensor array 16. The battery parameters measured and used herein include at least a battery voltage, a battery current, and a temperature of the battery 12, along with an ambient temperature of the surrounding environment. The EMU 18 may be configured to determine a state of charge (SOC), a state of health (SOH), and an open-circuit voltage (OCV) of the battery 12 as part of its programmed functionality, along with its present charging/discharging/open state or operating mode.

As part of the contemplated battery monitoring process described herein, input signals (CC_{IN}) from the sensor array 16 are communicated to the EMU 18. The EMU 18 thereafter outputs electronic control signals (CC_{OUT}) to an external device 24, e.g., a graphical user interface (GUI) and/or a display screen, as well as to the disconnect switch 14 or other circuitry. The disconnect switch 14, which may be placed elsewhere in the schematic circuit of FIG. 1 including between the inverter circuit 23 and the AC-powered load 111, may be variously embodied as electromechanical contactors or relays, e.g., solid state relays (SSRs), operable to disconnect the battery 12 under certain fault conditions.

Although omitted from FIG. 1 for illustrative simplicity and clarity, the battery electric system 10 may also be equipped with a thermal management system as summarized above to help regulate temperature of the battery 12 during its normal operation, for example cooling plates, fins, heat sinks, coolant conduit, etc. Likewise, other circuit components such as fuses may be implemented to ensure the safety and reliability of the battery electric system 10 during its operation.

BATTERY DEGRADATION: When the representative battery 12 of FIG. 1 ages and degrades, the battery 12 may experience reduced capacity, increased internal resistance, and decreased voltage capability. With respect to reduced capacity, the ability of the battery 12 to hold a charge diminishes, i.e., a power capacity of the battery 12 will decrease more rapidly than when the battery 12 is new. Increased internal resistance reduces the efficiency of energy transfer, thus causing the battery 12 to heat up more during charging and discharging modes. Voltage drops are indicative of the degraded battery 12 not being able to maintain a stable voltage, which can affect performance of any load 11 or 111 ultimately powered by the battery 12.

Additionally with respect to rechargeable lithium-ion batteries and other high-energy batteries, it is recognized herein that energy loss in a new/properly functioning battery 12 should be approximately zero, i.e., the total energy into the battery 12 during a charging mode should approximately equal the total energy output from the battery 12 during a discharging mode. However, as the battery 12 degrades the total energy loss level/rate in the battery 12 will tend to increase in a detectable manner. Therefore, energy loss levels or rates above a threshold loss level, along with the temperature history of the battery 12, may be indicative of degradation of the battery 12. Accordingly, these values are used herein by the EMU 18 to monitor degradation of the battery 12 and trigger preventive or corrective actions when the degradation reaches an unacceptable level.

In terms of general battery physics, charging operations of a lithium-ion construction of the battery 12 causes lithium ions to migrate within the battery 12 and be absorbed onto electrode surfaces. This process is generally stable for a new battery 12. However, abnormal growth and formation of unstable lithium deposits can result from repeated charging cycles and/or increased charging rates, e.g., during repeated DC fast-charging of the battery 12. Clusters of deposits can form elongated branch-like structures, i.e., dendrites. Dendrites and other lithium accumulations increase the internal resistance, and thus internal resistance may be used herein as an indicator of degradation level of the battery 12.

Therefore, the battery 12 may exhibit energy loss at rates during different points of its operating life. The energy loss rates may progress from negligible degradation of the battery 12 when new through various intermediate levels indicative of minor degradation. Over time, the energy loss rates may indicate progressively more severe levels of degradation of the battery 12. Corresponding loss thresholds may be recorded in the memory 20 of FIG. 1 and used to determine the degradation level of the battery 12. Using such an analysis, the EMU 18 of FIG. 1 may thereafter initiate control or corrective actions as needed to protect the battery 12, the battery electric system 10, and users thereof.

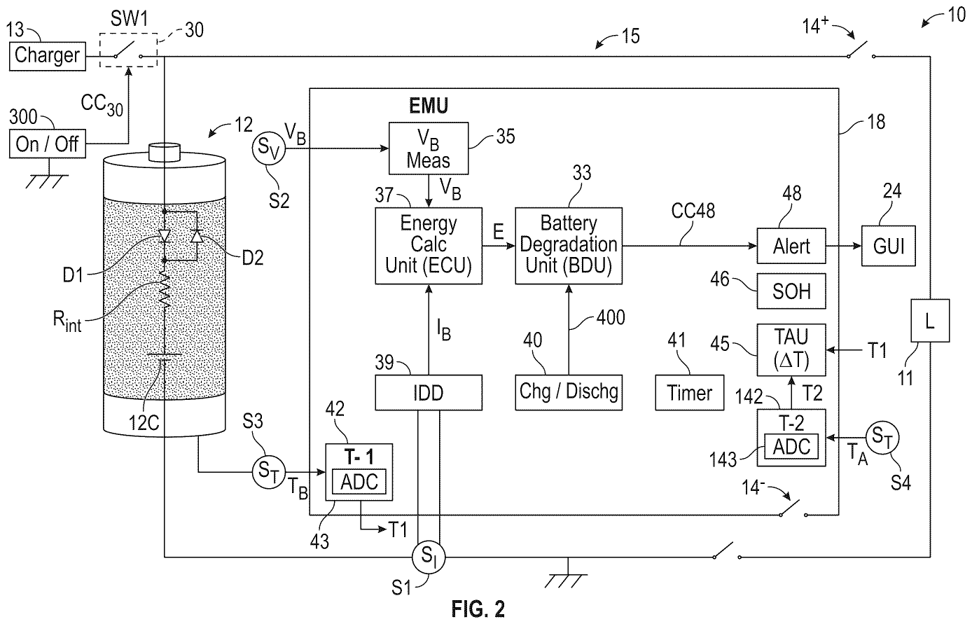

Referring to FIG. 2, portions of the battery electric system 10 of FIG. 1 are illustrated schematically as the battery monitoring system 15 and the load (L) 11. The battery 12 includes one or more electrochemical battery cells 12C, e.g., lithium-ion cells as noted above. The battery 12 is represented for simplicity as an equivalent circuit model having an internal resistance (Rᵢₙₜ) and respective charging and discharging diodes (D1) and (D2).

The battery 12 is disconnected from the load 11 during a charging mode via opening of the disconnect switch 14 of FIG. 1, i.e., one or both disconnect switches 14⁺ and/or 14⁻, with + and − respectively indicating connection to positive and negative voltage rails of the battery electric system 10. An optional charging switch (SW1) 30 may be commanded to close, e.g., by the EMU 18 or another charging controller 300, as indicated by arrow CC₃₀ and corresponding label “On/Off”. Performance of this action electrically connects the battery 12 to the battery charger 13. The battery charger 13 may be connected to an offboard power supply (not shown), such as grid power. When the power supply is an AC outlet, the battery charger 13 includes an internal AC/DC converter (not shown) operable to convert, filter, and output suitable DC voltage and current waveforms to the battery 12 for charging.

A current sensor (S₁) S1, which is a component of the sensor array 16 of FIG. 1 described above, may be used to measure the battery current (I_{B}), with a current measurement block (IDD) 39 determining flow direction and therefore determining whether the battery 12 is in a charging or discharging mode. The battery 12 is removed from the battery charger 13 when the battery 12 is in use (discharging mode), with removal of the battery 12 from the battery charger 13 automatically opening the charging switch 30 in a typical embodiment.

In a possible implementation of the EMU 18, corresponding hardware and software modules or blocks may be implemented to perform the requisite processing functions of the method 50 (FIG. 4). The EMU 18 includes a voltage measurement block (V_{B} Meas) 35. This logic may be implemented using a voltage sensor (S_{V}) S2 of the sensor array 16 (FIG. 1), with the measured battery voltage (V_{B}) periodically measured by or communicated to the voltage measurement block 35 and stored in non-volatile portions of the memory 20 of FIG. 1. An energy calculation unit (ECU) 37 in the illustrated topology receives the measured battery voltage (V_{B}) and the measured battery current (I_{B}), and uses these battery parameters to calculate a total energy level (E) as described below. A charge/discharge detection block (Chg/Dischg) 40 senses current flow direction to determine when the battery 12 of FIGS. 1 and 2 is a charging or discharging mode, with the charging/discharging mode reported to a battery degradation unit (BDU) 33 as a flow direction signal 400. As used herein, the terms “unit”, “block”, and similar terms refer to associated hardware and software for performing a described task, unless otherwise noted.

The EMU 18 illustrated in FIG. 2 also considers battery temperature (T_{B}), e.g., cell or pack temperature, and ambient temperature (T_{A}) in evaluating the degradation level and calculating a numeric state of health (SOH) of the battery 12. To that end, the EMU 18 is equipped with first and second temperature measurement blocks (T-1 and T-2) 42 and 142, respectively, both of which are in communication with a corresponding temperature sensor (S_{T}) S3 and S4, e.g., a thermistor or a thermocouple.

The measured battery temperature (T_{B}) may be requested by, communicated to, and recorded by the first temperature measurement block 42 as a first temperature (T1), possibly with assistance of an analog-to-digital converter 43. Similarly, the second temperature measurement block 142 and another analog-to-digital converter 143 may process the ambient temperature (T_{A}) from sensor S4 as part of the method 50 of FIG. 4 to provide a second temperature (T2). The respective first and second temperatures T1 and T2 are communicated to a temperature accumulation unit (TAU ΔT) 45 operable for determining a temperature differential (ΔT) for use in determining a degradation level and SOH of the battery 12.

Actions may be taken by the EMU 18 of FIG. 2 when a degradation level of the battery 12 is high relative to one or more predetermined degradation thresholds. This may occur when a rate of increase of energy loss of the battery 12 exceeds a predetermined energy loss threshold, with multiple such thresholds possibly corresponding to different degradation levels of the battery 12. In such a case, alerts may be communicated by the EMU 18 via the output signals (CC_{OUT}) of FIG. 1, for instance to the external device 24 or another external audio and/or visual device via control signals (CC₄₈) to an alert module 48 configured for this purpose. An optional SOH block 46 may be used in one or more embodiments to calculate a numeric SOH of the battery 12 using the calculations of the BDU 33 as noted below.

Depending on the application, the alerts may entail audible alarms, indicator lights, text messages, haptic feedback, and the like, which may include a request to discard or replace the battery 12. When the EMU 18 determines that failure of the battery 12 is imminent, the EMU 18 may take other preventive measures such as disconnecting the load 11 or preventing charging via the battery charger 13. Such actions may help prevent thermal damage to the surrounding environment or, for wearable versions of the battery electric system 10, to a user of the wearable device 21D of FIG. 1. A timer 41 is also included in the hardware of the EMU 18, with the timer 41 and other components of the EMU 18 of FIG. 2 used as set forth below with reference to method 50 of FIG. 4.

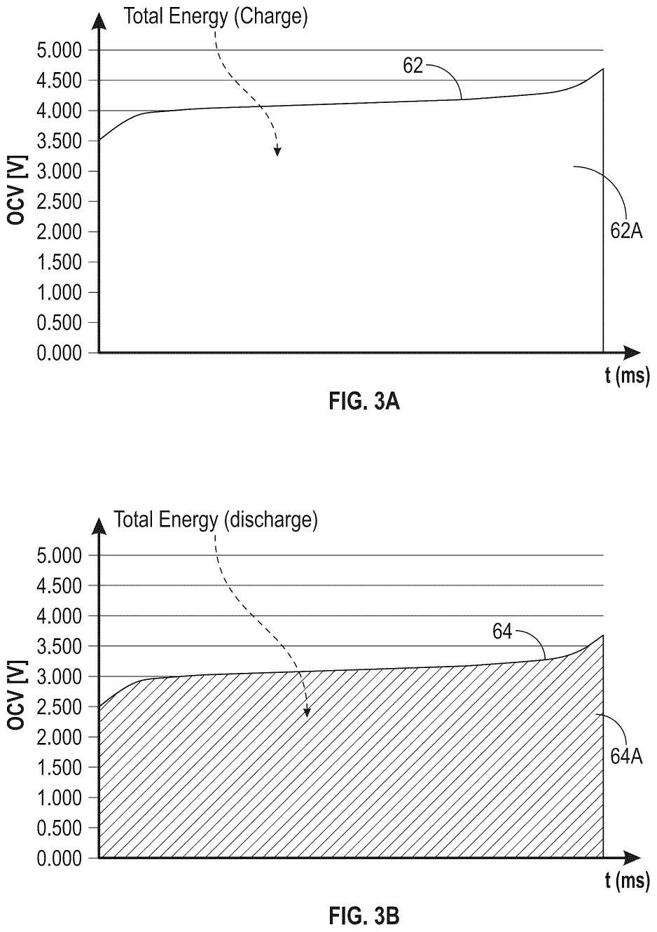

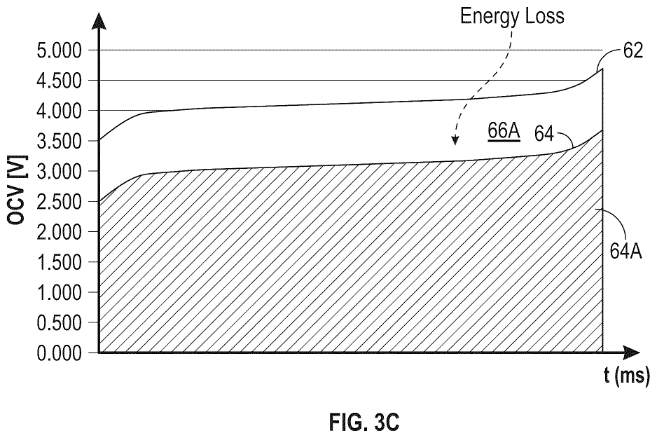

Referring briefly to the representative OCV-time plots of FIGS. 3A, 3B, and 3C, with time in millisecond (ms) depicted on the horizontal axis and OCV in volts (V) depicted on the vertical axis, the EMU 18 evaluates degradation of the battery 12 of FIGS. 1 and 2 using the principle of energy loss. As noted above, energy loss in the battery 12 increases as the battery 12 degrades. The area 62A under an OCV curve 62 in FIG. 3A represents the total energy input to the battery 12 during a charging operation, i.e., when the battery 12 is connected to the battery charger 13 of FIGS. 1 and 2. Similarly, the area 64A under an OCV curve 64 of OCV data in FIG. 3B represents the total energy output of the battery 12 during discharging of the battery 12. Thus, total energy loss as considered herein is represented by the area 66A of FIG. 3C between OCV curves 62 and 64, i.e., energy loss=charge energy (FIG. 3A)−discharge energy (FIG. 3B).

Referring now to FIG. 4, the method 50 is described below as a sequence of steps or logic blocks each embodied as computer-readable instructions. Such instructions may be recorded in the memory 20 of the EMU 18 shown in FIGS. 1 and 2 or in another accessible non-volatile, non-transitory memory location. The instructions are executable by the processor 19 to cause the processor 19, and thus the EMU 18, to perform the described functions. To that end, the memory 20 may include non-volatile memory portions or components, for instance magnetic or optical media, CD-ROM, and/or solid-state/semiconductor memory. The processor 19 may encompass one or more control modules, control units, microprocessor chips, Application Specific Integrated Circuit(s) (ASIC), Field-Programmable Gate Array(s) (FPGA(s)), electronic circuit(s), or central processing units. Non-transitory components of the memory 20 used herein are capable of storing machine-readable instructions in the form of one or more software or firmware programs or routines, combinational logic circuit(s), input/output circuit(s) and devices, signal conditioning and buffer circuitry and other components that can be accessed by one or more of the processors 19 to provide a described functionality.

An exemplary embodiment of the method 50 commences with block B52 (“Operate (12)”) with operation of the battery 12 of FIG. 1. For instance, the EMU 18 and processor 19 may perform the method 50 in response to the battery electric system 10 being initially turned on. The method 50 proceeds to block B54 while the battery 12 is in operation.

Block B54 (“Detect Mode”) entails detecting the operating mode of the battery 12. Block B54 may include using the current sensor S1 and blocks 39 and 40 (FIG. 2) to determine a current flow direction, and to communicate the flow direction as the flow direction signal 400, e.g., a voltage signal. The method 50 proceeds to block B56 once the operating mode of the battery 12 has been detected.

Block B56 (“Charging?”) includes determining, using the current data from block B54, whether the battery 12 is in a charging mode, i.e., the current measured at block B54 is flowing into the battery 12. The method 50 proceeds to block B58 when the battery 12 is in the charging mode. The method 50 otherwise proceeds to block B57.

At block B57 (“Discharging?”), the method 50 of FIG. 4 determines whether the battery 12 of FIG. 1 is in a discharging mode, i.e., the current measured at block B54 is flowing out of the battery 12. The timer 41 of FIG. 2 may be started when current flow is first detected. The method 50 proceeds to block B59 when the battery 12 is in a discharging mode. The method 50 otherwise returns to block B52.

At block B58 (“Set Flag-C”), the EMU 18 of FIG. 2 sets a bit flag or other register value indicative of the detected charging mode of the battery 12. The method 50 thereafter proceeds to block B60.

At block B59 (“Set Flag-D”), the EMU 18 of FIG. 1 sets a bit flag indicative of the detected discharging mode of the battery 12. The method 50 thereafter proceeds to block B60.

With continued reference to FIG. 4, block B60 (“Measure I_{B}, V_{B}”) entails measuring the battery current (I_{B}) and voltage (V_{B}) via the sensor suite 16 shown in FIG. 1. The measured battery current and voltage are then saved in a corresponding data bin of memory 20 based on the value of the bit flag (blocks B58 and B59) that existed at the time block B60 was performed. That is, if a bit flag indicative of the charging mode was set at block B58, then the battery current and voltage measured at block B60 would be saved to a designated charging bin. Likewise, the battery current and voltage measured at block B60 would be saved to a designated discharging bin if the bit flag was indicative of the discharging mode. The method 50 thereafter proceeds to block B62.

Block B62 (“CALC (P)”) includes calculating a power level in a non-volatile portion of memory 20. As appreciated in the art, power may be calculated as the product of the two values measured at block B60, i.e., P=I_{B}×V_{B}. The power level is temporarily stored in memory 20. The method 50 thereafter proceeds to block B64.

At block B64 (“Integrate (P)”), the EMU 18 integrates the power level over time to determine a total energy value, i.e., area 62A of FIG. 3A during the charging mode or area 64A of FIG. 3B during the discharging mode of the battery 12. The method 50 thereafter proceeds to block B66.

At block B66 (“Record in Register C, D”), the EMU 18 records the total energy value from block B64 in a corresponding register depending on whether the energy value was determined during the charging mode (register C) or the discharging mode (register D). Thus, two distinct energy registers exist that the EMU 18 is able to reference later in this particular embodiment of the method 50. The method 50 thereafter proceeds to block B68.

At block B68 (“t=t_{CAL}?”), the method 50 compares the counter value of the timer 41 (FIG. 1) to a calibrated duration. The calibrated duration may be application-specific, e.g., once per month having a predetermined number of charge/discharge cycles, for instance fifteen cycles. The method 50 returns to block B52 when the calibrated duration has not been satisfied, and proceeds in the alternative to block B70.

Block B70 (“Total E-Loss Rate”) includes calculating the energy loss rate in the battery 12. Block B70 may be performed by the EMU 18 by comparing the charge and discharge energy values from the respective charge and discharge energy registers (block B66), i.e.:

$${R}_{EL} = \frac{( {E}_{C} - {E}_{D} )}{{E}_{C}} \times 100 \%$$

where R_{EL} is the energy loss rate, E_{C} is the charge energy, and ED is the discharge energy. This value corresponds to area 66A of FIG. 3C. The method 50 then proceeds to block B72.

At block B72 (“>CAL?”), the method 50 includes determining whether the total energy loss rate from block B70 exceeds a calibrated loss rate threshold, e.g., about 20% to about 30%, or about 25% in a particular implementation. The loss threshold may be adjusted or set by the processor in one or more implementations, within this range or in another range/value depending on the application. For purposes of this disclosure, “about” means “near, or nearly at,” or “within 0-5% of,” or “within acceptable manufacturing tolerances,” or any logical combination thereof. The method 50 proceeds to block B74 when the total energy loss rate exceeds the calibrated loss rate threshold, and returns to block B52 in the alternative when the total energy loss rate remains less than the calibrated loss rate threshold.

Block B74 (“T_{ACC}”) includes determining the temperature accumulation history of the battery 12. As shown in FIG. 2, the temperature accumulation unit 45 determines ΔT as the difference between the first and second temperatures T1 and T2, i.e., the processed measured battery temperature (T_{B}) from temperature measurement block 42 when the battery 12 is charging, e.g., a cell temperature, and ambient temperature (T_{A}) as determined by temperature measurement block 142. The ΔT values are recorded in non-volatile portions of the memory 20 over time to monitor temperature accumulation history. The method 50 proceeds to block B76 when the temperature accumulation history has been determined.

Block B76 (“12=Degraded?”) includes determining, via the EMU 18, whether the battery 12 has degraded below a tolerable level. Block B76, which is performed when the total energy loss rate from block B70 exceeds an energy loss threshold, may include comparing a peak value or trend in the temperature accumulation history to a predetermined threshold to determine whether the battery 12 is unacceptably degraded. Thus, the EMU 18 looks not only to total energy loss in the battery 12, but also to its temperature history when evaluating the SOH of the battery 12. Information regarding the degradation state may be communicated to the SOH block 46 (FIG. 2), which in turn may track the numeric SOH of the battery 12 as it declines over time. Doing so provides the EMU 18 with the capability of preemptively alerting maintenance personnel or operators to the need to replace the battery 12 well before the battery 12 reaches a problematic state of degradation.

In some embodiments, each degradation threshold may be associated with a particular preventive control action. “Preventive” as contemplated herein refers to an action that notifies a user of the battery electric system 10 of FIG. 1 that the SOH or performance of the battery 12 is compromised in some way. When the battery 12 has degraded to only a mild extent, the preventive action may take on a less urgent tone or mechanism, typically without the EMU 18 intervening in operation of the battery 12. Text messages, audio/visual alerts, or other information may be communicated to the user in such an instance. However, as the degradation level becomes more significant, e.g., when exceeding escalating degradation thresholds, the EMU 18 may escalate the preventive action response in terms of its urgency, as well as possibly intervening in the control of the battery 12 itself. The method 50 proceeds to block B78 when the EMU 18 has determined that the battery 12 has degraded below a tolerable level. The method 50 repeats block B52 when the temperature history of the battery 12 does not indicate such degradation.

At block B72 (“Generate Alert”), the EMU 18 may use the alert module 48 to generate an alert message, which may be transmitted to the external device 24 as a control action. This action may entail transmitting an SOH notice to the external device 24. Distinct levels of alerts or warning messages may be communicated this manner. An alert message communicated by the EMU 18 in response to a less urgent condition is itself less urgent in comparison to the alert message communicated in response to the more urgent condition.

Using an illustrative example, an SMS text message may be transmitted to the external device 24 based on the SOH level recommending replacement or service of the battery 12 within an extended timeframe or with unstated urgency, e.g., “battery approaching end of useful life-service recommended.” Levels of degradation may be represented as numeric SOH values, for instance with an SOH of “1” corresponding to a perfectly healthy battery 12 and an SOH of “0” corresponding to a fully degraded/inoperable battery 12. Values in between the normalized extremes of this exemplary range may correspond to progressively deteriorated states of the battery, e.g., the battery 12 described herein, with an SOH value closer to 0 being more degraded than those lying closer to an SOH value of 1.

If the battery electric system 10 of FIG. 1 is so equipped, a light or lamp may be lit with a corresponding color such as amber or yellow to visually alert users to the partially-degraded but still functional state of the battery 12. The urgency of the alert/messaging may be likewise elevated when exceeding the highest t degradation thresholds. For example, the above text example could be replaced with a more urgent phrasing such as “battery condition poor-immediate service recommended.” The optional light may be illuminated in a universally understood color such as red in this example, and/or a light may be caused to pulsate or blink to elevate the alert status in a discernable manner. Audible warning tones may likewise be sounded to draw a user's attention to the possible imminent failure of the battery 12.

At some point, the EMU 18 of FIG. 1 may determine that continued use of the battery 12 would be potentially detrimental to the health and safety of the battery electric system 10 and possible users thereof. In this instance, the EMU 18 may be caused to execute the protective action by commanding the disconnect switch 14 (FIG. 1) to open and thereby disconnect the battery 12 from the load 11 (or 111). Opening of the disconnect switch 14 effectively removes the battery 12 from a voltage bus connecting the battery 12 to the load 11/111, and therefore protects the load 11/111 from a discharge of power from the now-disconnected battery 12. Similarly, the EMU 18 may prevent the charging switch 30 from closing to prevent charging operations, for instance by transmitting an override or bypass signal to control logic of the battery charger 13 and/or charging switch 30. The battery 12 is thus isolated from the charging and discharging sides of the battery electric system 10.

Using the method 50 or embodiments thereof, high-energy batteries may be safely managed in a host of applications. The solutions presented herein use a relationship between energy loss and temperature history to enable early detection of potentially hazardous states of such batteries, e.g., the battery 12 of FIG. 1. These and other benefits of the present teachings will be readily appreciated by those skilled in the art now having the benefit of the foregoing disclosure.

While several modes for carrying out the many aspects of the present teachings have been described in detail, those familiar with the art to which these teachings relate will recognize various alternative aspects for practicing the present teachings that are within the scope of the appended claims. The above description and accompanying drawings are illustrative and exemplary of the entire range of alternative embodiments that an ordinarily skilled artisan would recognize as implied by, structurally and/or functionally equivalent to, or otherwise rendered obvious based upon the included content, and not as limited solely to those explicitly depicted and/or described embodiments. Moreover, the present concepts expressly include combinations and sub-combinations of the described elements and features. The detailed description and the drawings are supportive and descriptive of the present teachings, with the scope of the present teachings defined solely by the claims.

What is claimed is:

1. A battery monitoring system for a battery, comprising:
a sensor array configured to measure battery parameters, including an ambient temperature and a battery voltage, a battery current, and a battery temperature of the battery;
a processor; and
a non-transitory computer-readable storage medium (“memory”), the memory including instructions executable by the processor to cause the processor to:
record the battery parameters from the sensor array during a charging mode and a discharging mode of the battery, respectively;
determine an accumulated temperature history of the battery using the ambient temperature and the battery temperature;
calculate a total energy loss level of the battery using the battery voltage and the battery current; and
generate a degradation alert in response to the total energy loss level of the battery exceeding a loss threshold and the accumulated temperature history exceeding a temperature threshold.

2. The battery monitoring system of claim 1, wherein the instructions are executable by the processor to cause the processor to:
calculate an energy input rate of the battery during the charging mode using the battery parameters that are measured and recorded during the charging mode;
calculate an energy output rate of the battery during the discharging mode using the battery parameters that are measured and recorded during the discharging mode; and
calculate the total energy loss level of the battery as an energy loss rate using the energy output rate and the energy input rate.

3. The battery monitoring system of claim 1, wherein the loss threshold is about 20% to about 30%.

4. The battery monitoring system of claim 1, wherein the instructions are executable by the processor to cause the processor to:
determine a direction of current flow of the battery current using a current measurement block; and
detect an operating mode of the battery as the charging mode or the discharging mode using the direction of current flow of the battery current.

5. The battery monitoring system of claim 1, wherein the instructions are executable by the processor to cause the processor to:
calculate a power level of the battery as a product of the battery current and the battery voltage;
integrate the power level over time to determine a total energy value during the charging mode and during the discharging mode;
calculate an energy input rate of the battery using the total energy value during the charging mode; and
calculate an energy output rate of the battery using the total energy value during the discharging mode.

6. The battery monitoring system of claim 1, wherein the instructions are executable by the processor to cause the processor to:
calculate a numeric state of health (SOH) using the total energy loss level of the battery; and
transmit an SOH notice to an external device, the SOH notice being indicative of the numeric SOH.

7. A battery electric system, comprising:
a battery connectable to a load;
a sensor array configured to measure a set of battery parameters, including an ambient temperature and a battery voltage, a battery current, and a battery temperature of the battery; and
a battery monitoring system having:
a processor; and
a non-transitory computer-readable storage medium (“memory”), the memory having instructions executable by the processor to cause the battery monitoring system to:
measure and record the battery parameters during a charging mode and a discharging mode of the battery, respectively;
determine an accumulated temperature history of the battery using the ambient temperature and the battery temperature;
calculate a total energy loss level of the battery using the battery voltage and the battery current; and
generate a degradation alert in response to the total energy loss level exceeding a loss threshold and the accumulated temperature history exceeding a temperature threshold.

8. The battery electric system of claim 7, wherein the battery monitoring system is configured to:
calculate an energy input rate of the battery during the charging mode of the battery using the battery parameters that are measured and recorded during the charging mode;
calculate an energy output rate of the battery during the discharging mode using the battery parameters that are measured and recorded during the discharging mode; and
calculate the total energy loss level of the battery as an energy loss using the energy output rate and the energy input rate.

9. The battery electric system of claim 8, wherein the battery monitoring system is configured to:
calculate a power level as a product of the battery current and the battery voltage;
integrate the power level over time to determine a total energy value during the charging mode and during the discharging mode;
calculate the energy output rate of the battery using the total energy value during the charging mode; and
calculate the energy output rate of the battery using the total energy value during the discharging mode.

10. The battery electric system of claim 7, wherein the loss threshold is about 20% to about 30%.

11. The battery electric system of claim 7, wherein the battery monitoring system is configured to:
detect an operating mode of the battery as the charging mode or the discharging mode of the battery by determining a direction of current flow of the battery current using a current measurement block.

12. The battery electric system of claim 7, wherein the battery monitoring system is configured to:
calculate a numeric state of health (SOH) of the battery using the total energy loss level; and
transmit an SOH notice to an external device that is indicative of the numeric SOH of the battery.

13. The battery electric system of claim 7, wherein the battery is a lithium-ion battery or battery pack.

14. A method for monitoring degradation of a battery, comprising:
receiving battery parameters from a sensor array via a processor, the battery parameters including an ambient temperature and a battery voltage, a battery current, and a battery temperature of the battery;
recording the battery parameters during a charging mode and a discharging mode of the battery, respectively;
determining an accumulated temperature history of the battery via the processor using the ambient temperature and the battery temperature;
calculating a total energy loss level of the battery using the battery voltage and the battery current; and
transmitting a degradation alert to an external device in response to the total energy loss level exceeding a loss threshold and the accumulated temperature history exceeding a temperature threshold.

15. The method of claim 14, further comprising:
calculating an energy input rate of the battery using the battery parameters that are measured and recorded during the charging mode;
calculating an energy output rate of the battery using the battery parameters that are measured and recorded during the discharging mode; and
calculating the total energy loss level of the battery as an energy loss rate using the energy output rate and the energy input rate.

16. The method of claim 15, further comprising:
calculating the energy loss rate by subtracting the energy output rate from the energy input rate.

17. The method of claim 14, further comprising:
comparing the energy loss rate to the loss threshold, wherein the loss threshold is about 20% to about 30%.

18. The method of claim 14, further comprising:
determining a direction of current flow of the battery current using the processor; and
detecting an operating mode of the battery as the charging mode or the discharging mode of the battery based on the direction of current flow of the battery current.

19. The method of claim 14, further comprising:
calculating a power level as a product of the battery current and the battery voltage; and
integrating the power level over time to determine a total energy value during the charging mode and during the discharging mode.

20. The method of claim 14, further comprising:
calculating a numeric state of health (SOH) of the battery using the total energy loss level; and
transmitting an SOH notice to the external device, the SOH notice being indicative of the numeric SOH of the battery.
